(19) United States
(12) Patent Application Publication
(10) Pub. No.: US 2023/0389370 A1
(43) Pub. Date: Nov. 30, 2023

(54) DISPLAY DEVICE AND METHOD FOR MANUFACTURING DISPLAY DEVICE

(71) Applicant: Japan Display Inc., Tokyo (JP)

(72) Inventors: Yoshitaka OZEKI, Tokyo (JP); Nobutaka OZAKI, Tokyo (JP)

(21) Appl. No.: 18/202,403

(22) Filed: May 26, 2023

(30) Foreign Application Priority Data
May 30, 2022 (JP) 2022-088019

(51) Int. Cl. H10K 59/126; G09G 3/36; H10K 59/12; H10K 59/80

(52) U.S. Cl. CPC H10K 59/126; G09G 3/36; H10K 59/1201; H10K 59/80524; G09G 2300/0842

(57) ABSTRACT

A display device includes: an oxide semiconductor layer; a gate electrode facing the oxide semiconductor layer; a gate insulating layer between the oxide semiconductor layer and the gate electrode; a light-shielding layer overlapping part of the oxide semiconductor layer in a plan view; a first insulating layer covering the oxide semiconductor layer, the gate electrode, and the gate insulating layer, the first insulating layer including a first opening including a first side wall overlapping the light-shielding layer and a second side wall not overlapping the light-shielding layer in a plan view; and a transparent conductive layer arranged above the first insulating layer and connected to the oxide semiconductor layer via the first opening. The transparent conductive layer is arranged in an area overlapping the first side wall and is not arranged in at least part in an area overlapping the second side wall in a plan view.

### CROSS REFERENCE TO RELATED APPLICATIONS

This application claims the benefit of priority to Japanese Patent Application No. 2022-088019 filed on May 30, 2022, the entire contents of which are incorporated herein by reference.

### FIELD

One embodiment of the present invention relates to a display device and a method for manufacturing display device. In particular, one embodiment of the present invention relates to a display device and a method for manufacturing display device using a transistor having an oxide semiconductor.

### BACKGROUND

Recently, a transistor using an oxide semiconductor as a channel has been developed in place of an amorphous silicon, a low-temperature polysilicon, and a single-crystal silicon (e.g., Japanese laid-open patent publication No. 2015-187701 and Japanese laid-open patent publication No. 2020-025114). The transistor using the oxide semiconductor as the channel is formed in a simple-structured, low-temperature process similar to a transistor using an amorphous silicon as a channel. It is known that the transistor using the oxide semiconductor as the channel has higher mobility than the transistor using the amorphous silicon as the channel and has a very low off-current.

In order for a transistor in which an oxide semiconductor is used as a channel to have a stable operation, it is essential to reduce oxygen vacancies formed in the oxide semiconductor by supplying more oxygen to the oxide semiconductor in a manufacturing process for the transistor. As one method for supplying oxygen to the oxide semiconductor, Japanese laid-open patent publication No. 2015-187701 and Japanese laid-open patent publication No. 2020-025114 disclose a technique in which an insulating layer covering the oxide semiconductor is formed under the condition such that an insulating layer contains more oxygen.

In the case where a transistor in which an oxide semiconductor layer is used as a channel and a transparent conductive layer is used as a wiring connected to the oxide semiconductor layer is used as a pixel circuit of a display device, since both the oxide semiconductor layer and the transparent conductive layer have light transmittances, a pattern of the oxide semiconductor layer can be formed in a display area through which light is transmitted. The transparent conductive layer used as the wiring is connected to the oxide semiconductor layer through an opening arranged in an insulating layer between the oxide semiconductor layer and the transparent conductive layer.

In this configuration, a polarization state of a light incident in a direction orthogonal to a main surface of a substrate is changed by a refraction in the transparent conductive layer arranged on the side wall of the opening. Specifically, a linearly polarized light generated by one of a pair of polarizing plates arranged in the display device changes to a polarization state close to a circularly polarized light by the refraction. As a result, a light leakage occurs in a vicinity of an opening side wall, and a contrast of an image displayed by the display device is deteriorated.

### SUMMARY

A display device according to an embodiment of the present invention includes: an oxide semiconductor layer; a gate electrode facing the oxide semiconductor layer; a gate insulating layer between the oxide semiconductor layer and the gate electrode; a light-shielding layer overlapping part of the oxide semiconductor layer in a plan view; a first insulating layer covering the oxide semiconductor layer, the gate electrode, and the gate insulating layer, the first insulating layer including a first opening including a first side wall overlapping the light-shielding layer and a second side wall not overlapping the light-shielding layer in a plan view; and a transparent conductive layer arranged above the first insulating layer and connected to the oxide semiconductor layer via the first opening. The transparent conductive layer is arranged in an area overlapping the first side wall in a plan view, and the transparent conductive layer is not arranged in at least part in an area overlapping the second side wall in a plan view.

A display device according to an embodiment of the present invention includes: an oxide semiconductor layer; a gate electrode facing the oxide semiconductor layer; a gate insulating layer between the oxide semiconductor layer and the gate electrode; a light-shielding layer overlapping part of the oxide semiconductor layer in a plan view; a first insulating layer covering the oxide semiconductor layer, the gate electrode, the first insulating layer including a first opening overlapping the light-shielding layer in a plan view; and a transparent conductive layer arranged above the first insulating layer and connected to the oxide semiconductor layer via the first opening. The transparent conductive layer extends in a first direction from an area overlapping the light-shielding layer in a plan view beyond an end portion of the light-shielding layer, and an end portion of the first opening is positioned in the first direction side with respect to an end portion of the transparent conductive layer in a plan view.

A method for manufacturing display device according to an embodiment of the present invention includes: forming an oxide semiconductor layer, a gate electrode facing the oxide semiconductor layer, and a gate insulating layer between the oxide semiconductor layer and the gate electrode; forming a first insulating layer above the oxide semiconductor layer, the gate electrode, and the gate insulating layer; forming a first opening achieving the oxide semiconductor layer in the first insulating layer; forming a transparent conductive layer above the first insulating layer and inside the first opening; forming a resist above the transparent conductive layer so that a thickness of the resist inside the first opening is larger than a thickness of the resist above the first insulating layer; exposing a second side wall of the first opening from the resist while a first sidewall of the first opening and a bottom portion of the first opening are covered with the resist; and removing the transparent conductive layer arranged on the second sidewall.

### BRIEF DESCRIPTION OF DRAWINGS

FIG. 1A is a cross-sectional view showing an overview of a display device according to an embodiment of the present invention.

FIG. 1B is a cross-sectional view and a plan view showing a contact configuration of a transistor according to an embodiment of the present invention.

FIG. 10 is a cross-sectional view and a plan view showing a contact configuration of a transistor according to an embodiment of the present invention.

FIG. 2 is a plan view showing an overview of a display device according to an embodiment of the present invention.

FIG. 3 is a plan view for explaining a layout of each layer in a display device according to an embodiment of the present invention.

FIG. 4 is a plan view for explaining a layout of each layer in a display device according to an embodiment of the present invention.

FIG. 5 is a plan view for explaining a layout of each layer in a display device according to an embodiment of the present invention.

FIG. 6 is a plan view for explaining a layout of each layer in a display device according to an embodiment of the present invention.

FIG. 7 is a plan view for explaining a layout of each layer in a display device according to an embodiment of the present invention.

FIG. 8 is a plan view for explaining a layout of each layer in a display device according to an embodiment of the present invention.

FIG. 9 is a plan view for explaining a layout of each layer in a display device according to an embodiment of the present invention.

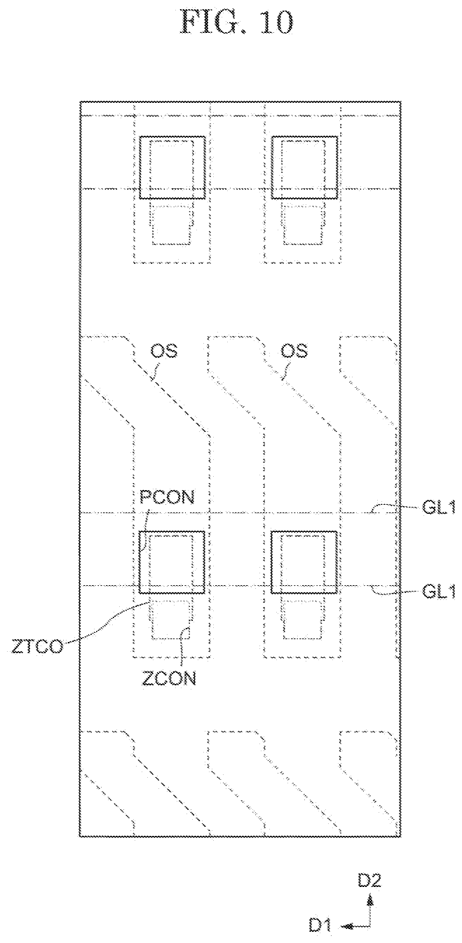

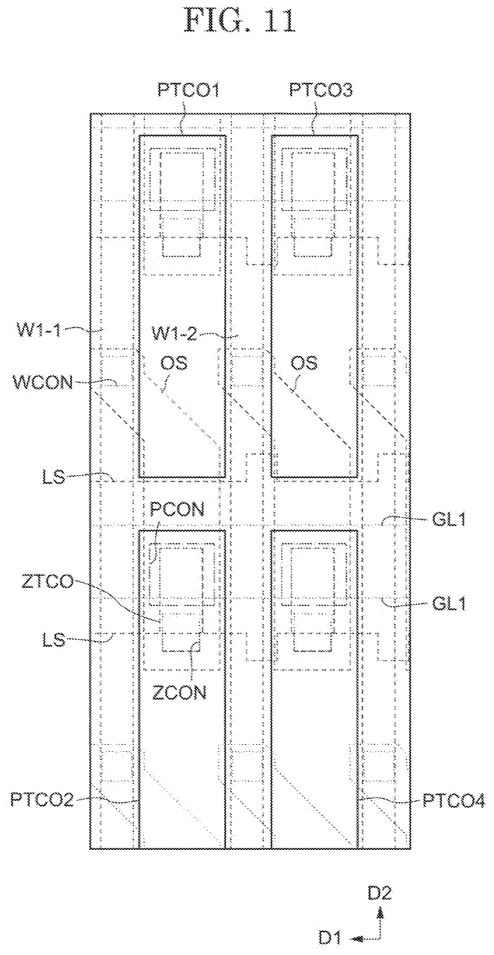

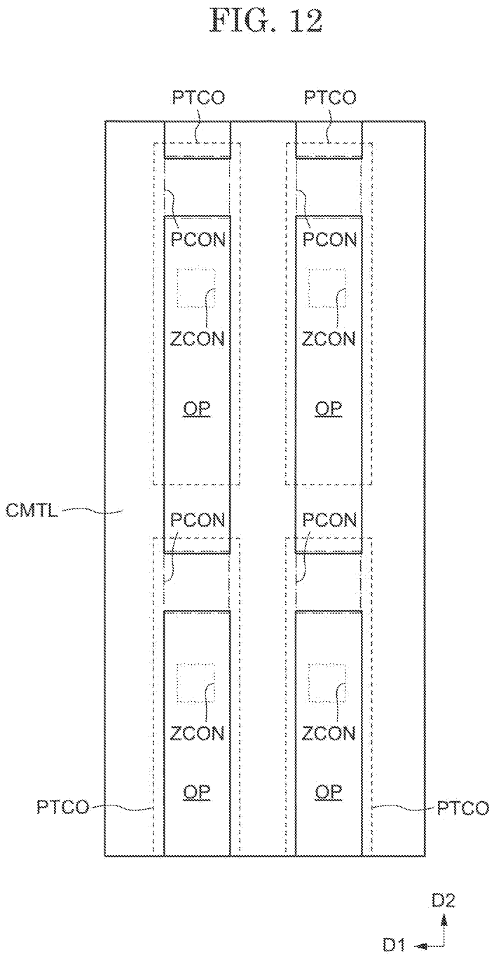

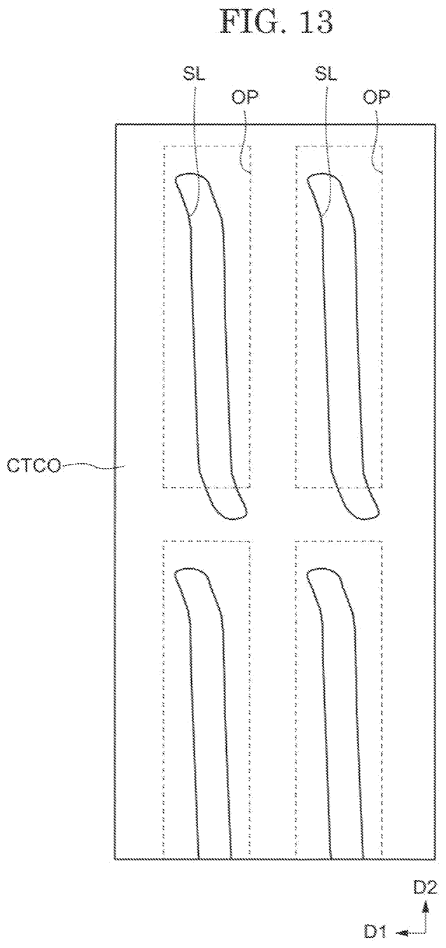

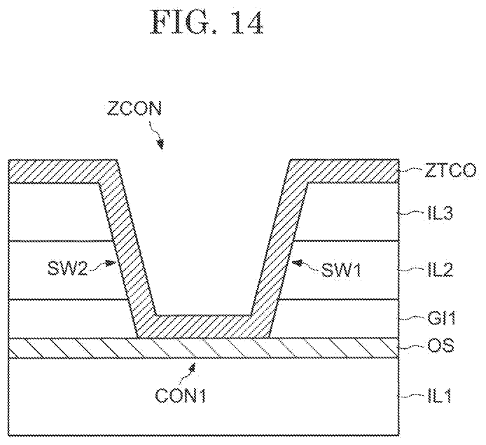

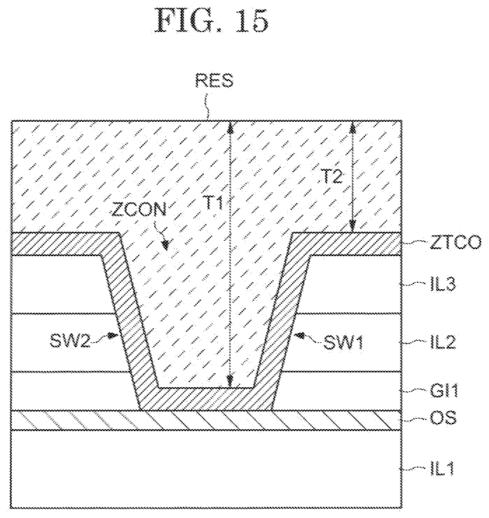

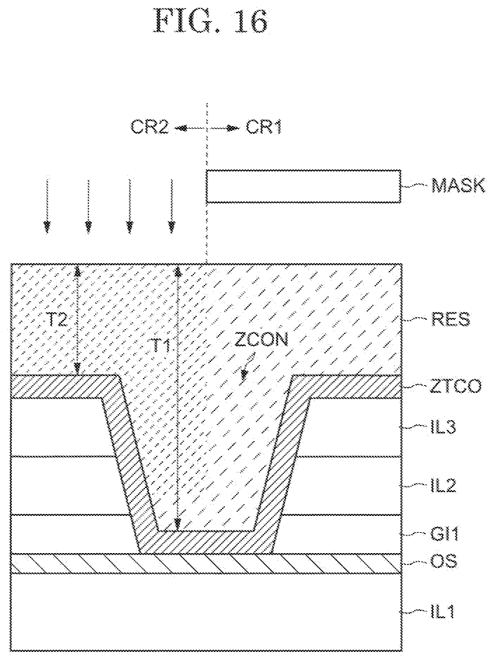

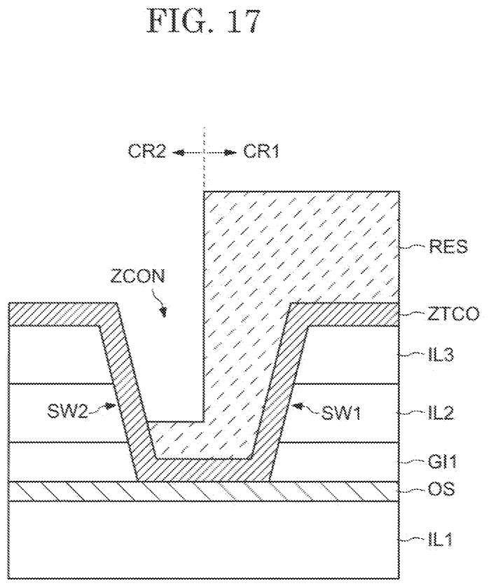

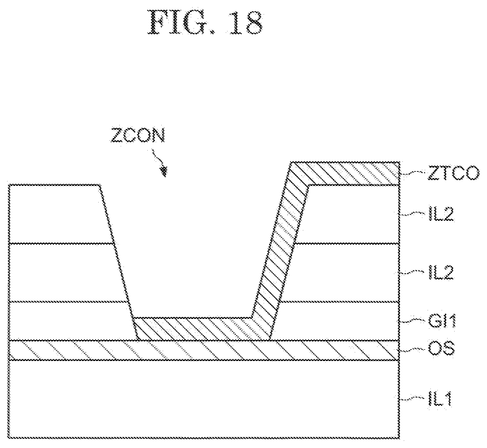

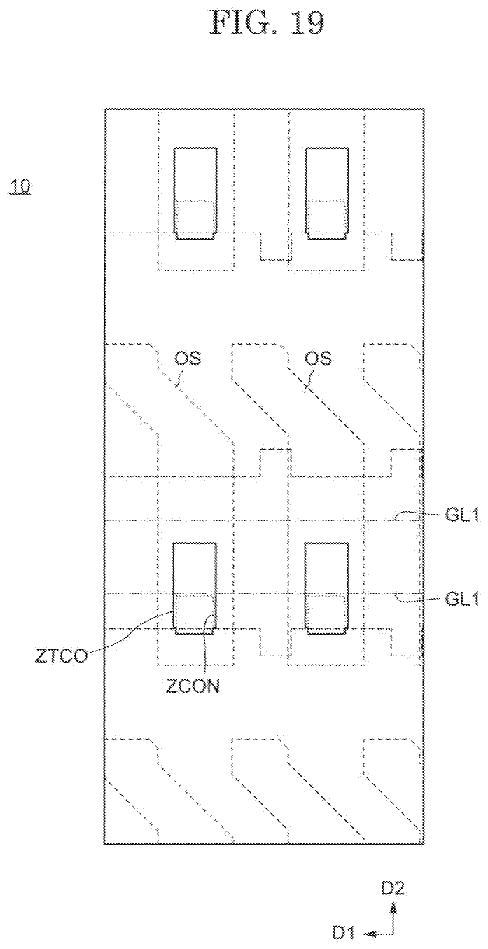

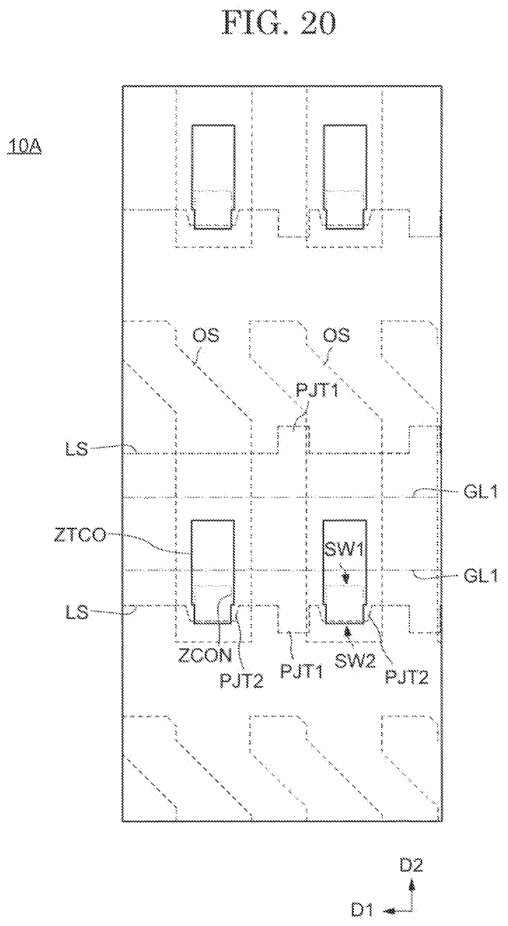

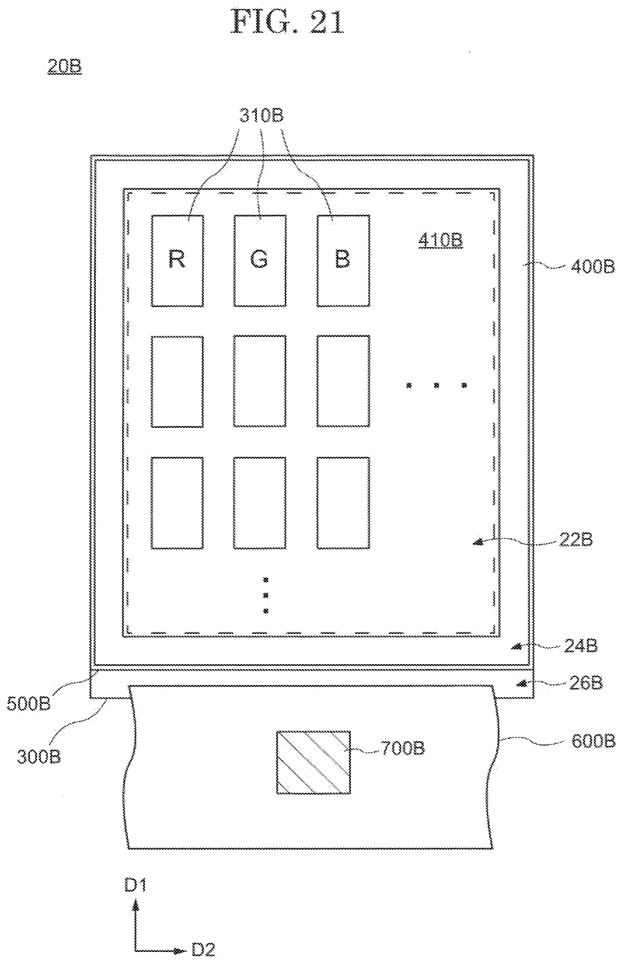

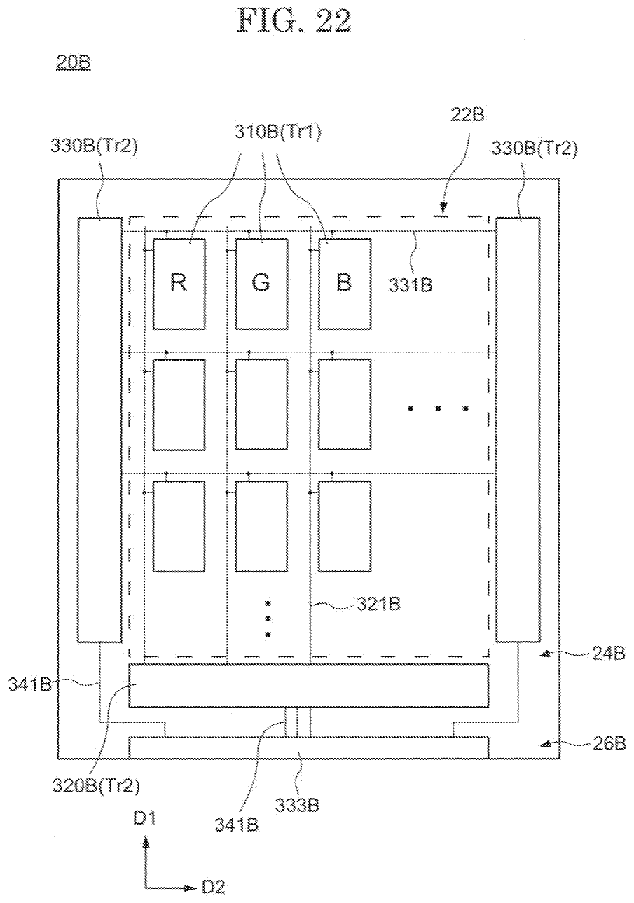

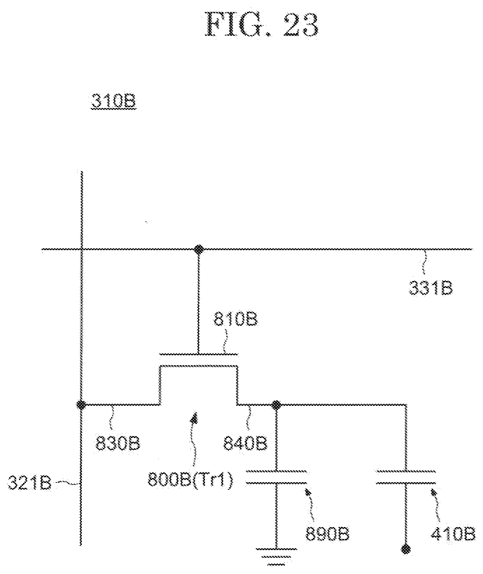

FIG. 10 is a plan view for explaining a layout of each layer in a display device according to an embodiment of the present invention.

FIG. 11 is a plan view for explaining a layout of each layer in a display device according to an embodiment of the present invention.

FIG. 12 is a plan view for explaining a layout of each layer in a display device according to an embodiment of the present invention.

FIG. 13 is a plan view for explaining a layout of each layer in a display device according to an embodiment of the present invention.

FIG. 14 is a cross-sectional view showing a method of manufacturing display device according to an embodiment of the present invention.

FIG. 15 is a cross-sectional view showing a method of manufacturing display device according to an embodiment of the present invention.

FIG. 16 is a cross-sectional view showing a method of manufacturing display device according to an embodiment of the present invention.

FIG. 17 is a cross-sectional view showing a method of manufacturing display device according to an embodiment of the present invention.

FIG. 18 is a cross-sectional view showing a method of manufacturing display device according to an embodiment of the present invention.

FIG. 19 is a plan view for explaining a layout of each layer in a display device according to a modification of an embodiment of the present invention.

FIG. 20 is a plan view for explaining a layout of each layer in a display device according to an embodiment of the present invention.

FIG. 21 is a plan view showing an overview of a display device according to an embodiment of the present invention.

FIG. 22 is a block diagram showing a circuit configuration of a display device according to an embodiment of the present invention.

FIG. 23 is a circuit diagram showing a pixel circuit of a display device according to an embodiment of the present invention.

### DESCRIPTION OF EMBODIMENTS

Embodiments of the present invention will be described below with reference to the drawings. The following disclosure is merely an example. A configuration that can be easily conceived by a person skilled in the art by appropriately changing the configuration of the embodiment while maintaining the gist of the invention is naturally included in the scope of the present invention. For the sake of clarity of description, the drawings may be schematically represented with respect to widths, thicknesses, shapes, and the like of the respective portions in comparison with actual embodiments. However, the shape shown is merely an example and does not limit the interpretation of the present invention. In this specification and each of the drawings, the same symbols are assigned to the same components as those described previously with reference to the preceding drawings, and a detailed description thereof may be omitted as appropriate.

In each embodiments of the present invention, a direction from a substrate to an oxide semiconductor layer is referred to as upper or above. On the contrary, a direction from the oxide semiconductor layer to the substrate is referred to as lower or below. As described above, for convenience of explanation, although the phrase “above” or “below” is used for explanation, for example, a vertical relationship between the substrate and the oxide semiconductor layer may be arranged in a different direction from that shown in the drawing. In the following description, for example, the expression “the oxide semiconductor layer on the substrate” merely describes the vertical relationship between the substrate and the oxide semiconductor layer as described above, and other members may be arranged between the substrate and the oxide semiconductor layer. Above or below means a stacking order in a structure in which multiple layers are stacked, and in the case where it is expressed as a pixel electrode above a transistor, it may be a positional relationship where the transistor and the pixel electrode do not overlap each other in a plan view. On the other hand, in the case where it is expressed as a pixel electrode vertically above a transistor, it means a positional relationship where the transistor and the pixel electrode overlap each other in a plan view.

“Display device” refers to a structure configured to display an image using electro-optic layers. For example, the term display device may refer to a display panel including the electro-optic layer, or it may refer to a structure in which other optical members (e.g., polarizing member, backlight, touch panel, etc.) are attached to a display cell. The “electro-optic layer” can include a liquid crystal layer, an electroluminescence (EL) layer, an electrochromic (EC) layer, and an electrophoretic layer, as long as there is no technical contradiction. Therefore, although the embodiments described later will be described by exemplifying the liquid crystal display device including a liquid crystal layer as the display device, the structure in the present embodiment can be applied to a display device including the other electro-optical layers described above.

The expressions “α includes A, B, or C”, “a includes any of A, B, and C”, and “α includes one selected from a group consisting of A, B, and C” do not exclude the case where α includes multiple combinations of A to C unless otherwise specified. Furthermore, these expressions do not exclude the case where a includes other elements.

The following embodiments may be combined with each other as long as there is no technical contradiction.

It is an object of one embodiment of the present invention to improve luminance of display device. It is an object of one embodiment of the present invention to realize a highly performance display device.

### 1. First Embodiment

### [1-1. Configuration of Display Device 10]

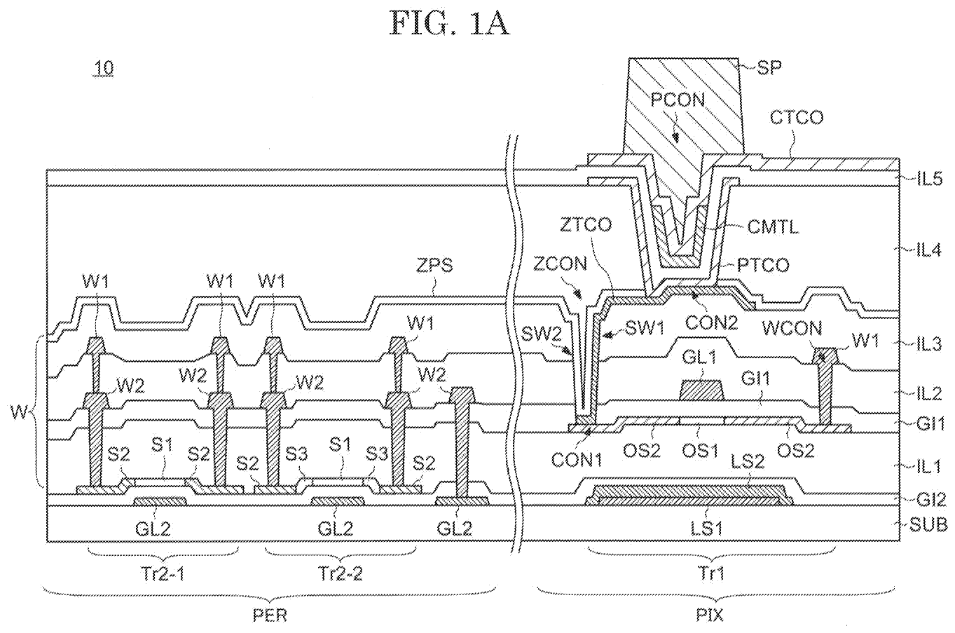

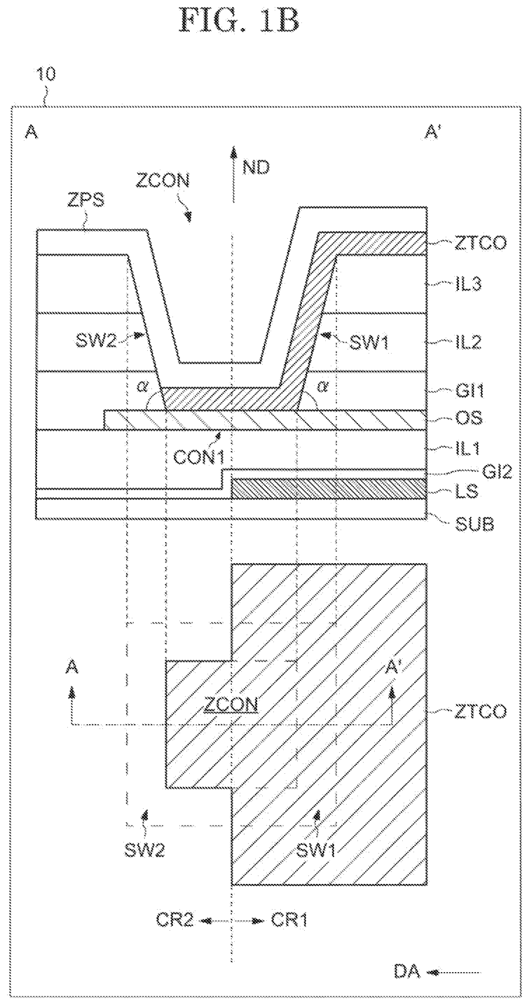

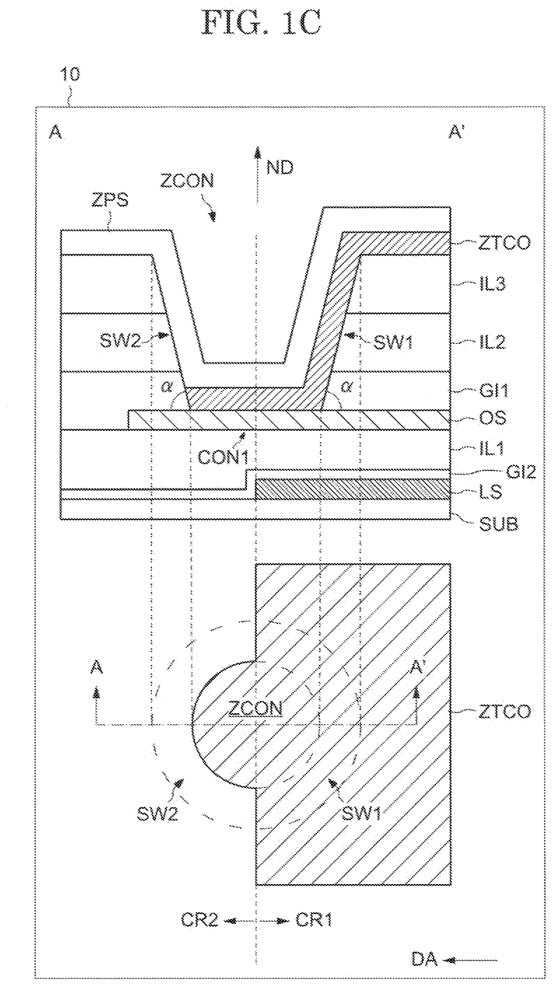

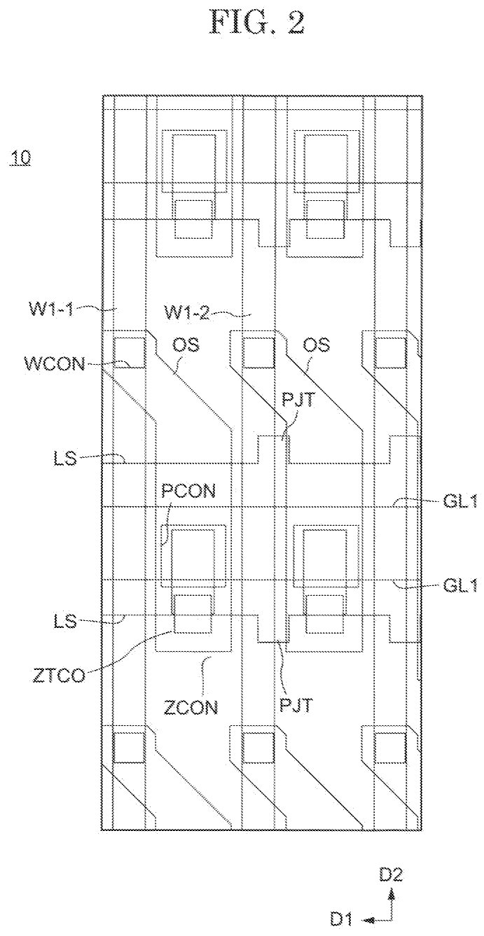

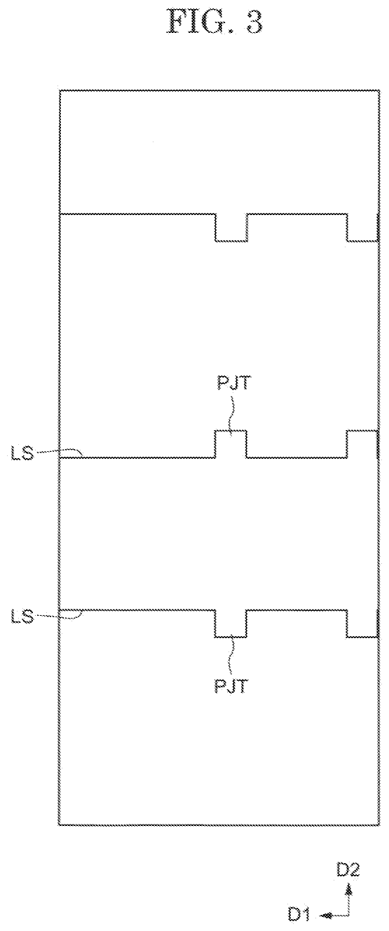

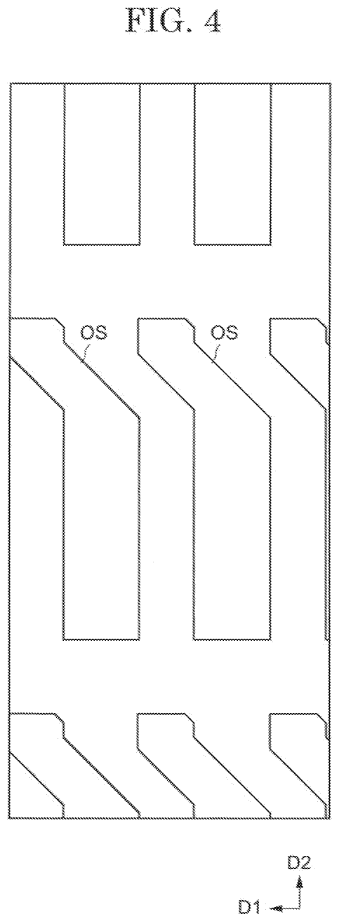

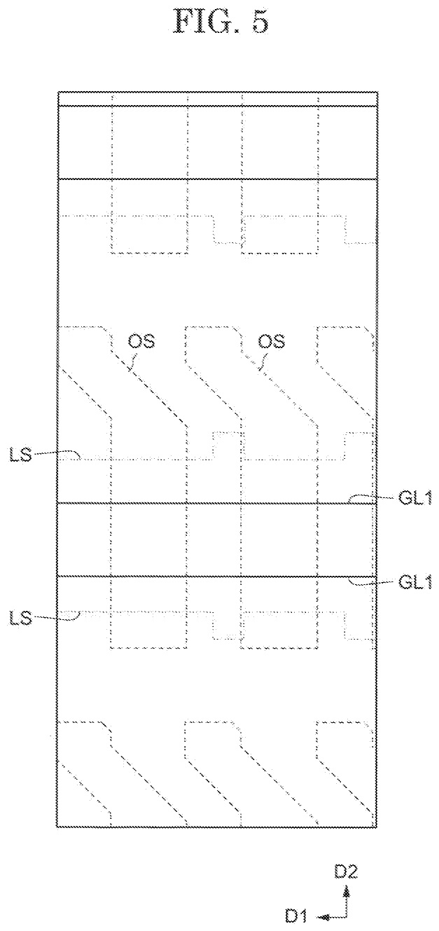

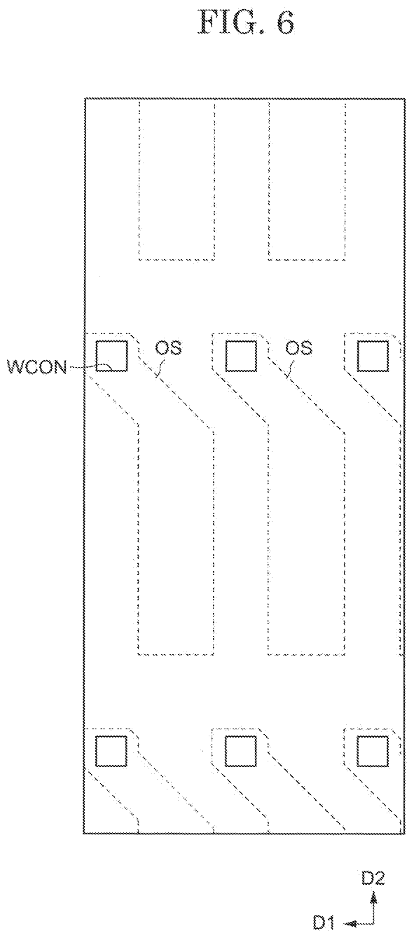

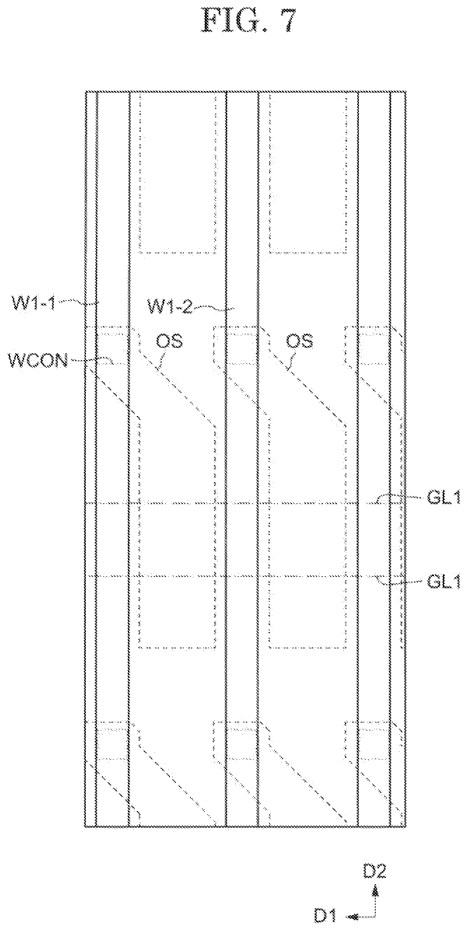

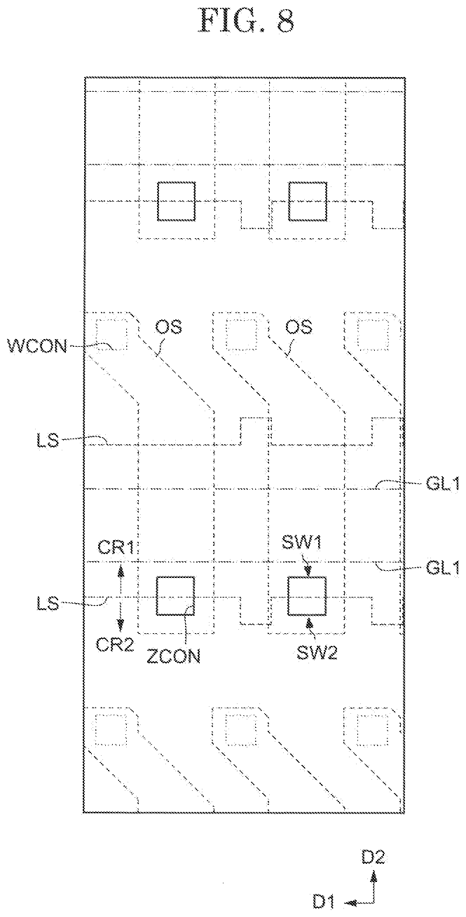

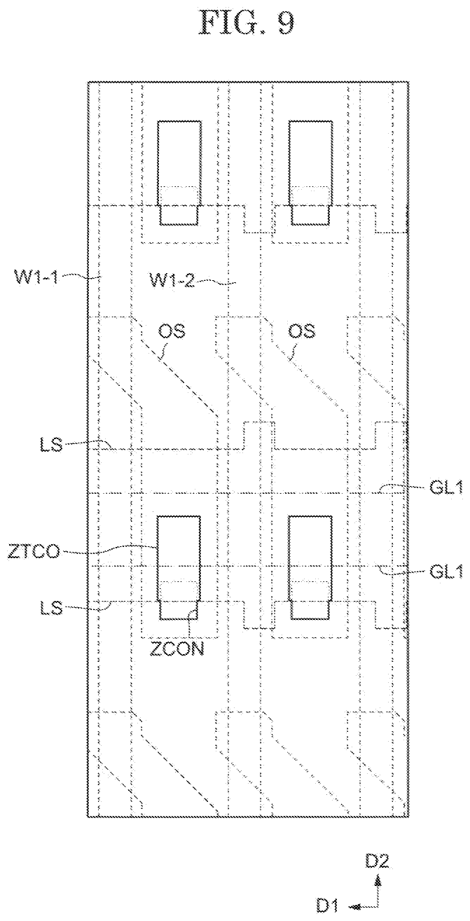

A configuration of a display device 10 according to an embodiment of the present invention will be described with reference to FIG. 1A to FIG. 18. FIG. 1A is a cross-sectional view showing an outline of a display device according to an embodiment of the present invention. FIG. 1B is a cross-sectional view and plan view showing a contact structure of a transistor according to an embodiment of the present invention. FIG. 2 is a plan view showing an outline of a display device according to an embodiment of the present invention. FIG. 3 to FIG. 13 are plan views showing layouts of each layer in a display device according to an embodiment of the present invention. FIG. 14 to FIG. 18 are cross-sectional views showing method for manufacturing display device according to an embodiment of the present invention. The cross-sectional view in FIG. 1A is for explaining a layer structure of the display device 10, which may not exactly match the plan view in FIG. 2.

As shown in FIG. 1A, the display device 10 includes a substrate SUB. The display device 10 also includes a transistor Tr1, a transistor Tr2 (Tr2-1 and Tr2-2), a wiring W (W1 and W2), a connecting electrode ZTCO, a pixel electrode PTCO, a common auxiliary electrode CMTL, and a common electrode CTCO on the substrate SUB. TCO is an abbreviation for Transparent Conductive Oxide. The transistor Tr1 is a transistor included in a pixel circuit PIX of the display device 10. The transistor Tr2 is a transistor included in a peripheral circuit PER. As will be described in detail later, the peripheral circuit PER is a circuit configured to drive the pixel circuit PIX.

### [1-2. Configuration of Transistor Tr1]

The transistor Tr1 includes an oxide semiconductor layer OS (OS1 and OS2) a gate insulating layer GI1, and a gate electrode GL1. The gate electrode GL1 faces the oxide semiconductor layer OS. The gate insulating layer GI1 is arranged between the oxide semiconductor layer OS and the gate electrode GL1. In the present embodiment, although a top gate type transistor in which the oxide semiconductor layer OS is arranged closer to the substrate SUB than the gate electrode GL1 is exemplified, a bottom gate type transistor in which a positional relationship between the gate electrode GL1 and the oxide semiconductor layer OS is reversed may be applied.

The oxide semiconductor layer OS includes oxide semiconductor layers OS1 and OS2. The oxide semiconductor layer OS1 is an oxide semiconductor layer in an area overlapping the gate electrode GL1 in a plan view. The oxide semiconductor layer OS1 functions as a semiconductor layer and is switched between a conductive state and a non-conductive state according to a voltage supplied to the gate electrode GL1. That is, the oxide semiconductor layer OS1 functions as a channel for the transistor Tr1. The oxide semiconductor layer OS2 functions as a conductive layer. The oxide semiconductor layers OS1 and OS2 are layers formed from the same oxide semiconductor layer. For example, the oxide semiconductor layer OS2 is a low resistance oxide semiconductor layer formed by doping impurities into a layer which has the same physical properties as the oxide semiconductor layer OS1.

An insulating layer IL2 is arranged above the gate electrode GL1. A wiring W1 is arranged above the insulating layer IL2. The wiring W1 is connected to the oxide semiconductor layer OS2 via an opening WCON arranged in the insulating layer IL2 and the gate insulating layer GI1. A data signal related to pixel gradation is transmitted to the wiring W1. An insulating layer IL3 is arranged above the insulating layer IL2 and the wiring W1. The connecting electrode ZTCO is arranged above the insulating layer IL3. The connecting electrode ZTCO is connected to the oxide semiconductor layered OS2 via an opening ZCON arranged in the insulating layers IL3 and IL2, and the gate insulating layer GI1. The connecting electrode ZTCO is in contact with the oxide semiconductor layer at a bottom portion of the opening ZCON. The connecting electrode ZTCO is a transparent conductive layer. The detail structure of the connecting electrode ZTCO in the opening ZCON will be described later.

The insulating layers IL2 and IL3 may also be referred to as a “first insulating layer”. The first insulating layer covers the oxide semiconductor layer OS, the gate electrode GL1, and the gate insulating layer GI1. The opening ZCON may be referred to as a “first opening”. Side walls of the opening ZCON are referred to as a first side wall SW1 and a second side wall SW2. The first side wall SW1 and the second side wall SW2 are side walls belonging to one opening ZCON, and are continuous within the one opening ZCON.

An area where the connecting electrode ZTCO and the oxide semiconductor layer OS2 are in contact with each other is referred to as a first contact area CON1. The connecting electrode ZTCO does not overlap the gate electrode GL1 and the wiring W1 in a plan view. As described above, the connecting electrode ZTCO is in contact with the oxide semiconductor layer OS2 in the first contact area CON1. The first contact area CON1 is included in the display area of a pixel in a plan view.

For example, in the case where a transparent conductive layer such as an ITO layer is formed in contact with a semiconductor layer such as a silicon layer, a surface of the semiconductor layer is oxidized by a process gas or oxygen ions at the time of a deposition of an ITO film. Since an oxide layer formed on the surface of the semiconductor layer is high resistance, a contact resistance between the semiconductor layer and the transparent conductive layer is increased. As a result, there is a defect in an electrical contact between the semiconductor layer and the transparent conductive layer. On the other hand, even if the above transparent conductive layer is formed so as to be in contact with the oxide semiconductor layer, a high resistance oxide layer as described above is not formed on a surface of the oxide semiconductor layer. Therefore, there is no defect in the electrical contact between the oxide semiconductor layer and the transparent conductive layer.

A barrier layer ZPS having moisture barrier property is arranged on the connecting electrode ZTCO and on the insulating layer IL3. The barrier layers ZPS are also arranged inside the opening ZCON. The barrier layers ZPS are arranged along the first side wall SW1 and the second side wall SW2. In other words, the barrier layer ZPS covers an upper surface of the insulating layer IL3 and the opening ZCON, and covers the connecting electrode ZTCO and the second side wall SW2 inside the opening ZCON.

An insulating layer IL4 is arranged above the barrier layer ZPS. The insulating layer IL4 eases (flattens) a step formed from a structure arranged below the insulating layer IL4. The insulating layer IL4 may be referred to as a planarization film. The pixel electrode PTCO is arranged above the insulating layer IL4. The pixel electrode PTCO is connected to the connecting electrode ZTCO via an opening PCON (second opening) arranged in the insulating layer IL4 and the barrier layer ZPS. An area where the connecting electrode ZTCO and the pixel electrode PTCO are in contact with each other is referred to as a second contact area CON2. The second contact area CON2 overlaps the gate electrode GL1 in a plan view. The pixel electrode PTCO is a transparent conductive layer. The barrier layer ZPS and the insulating layer IL4 may be collectively referred to as “second insulating layer.” However, only the barrier layer ZPS may be referred to as “second insulating layer.” The second insulating layer is also arranged in the opening ZCON. That is, it may be referred that the second insulating layer is arranged along with the first side wall SW1 and the second side wall SW2.

An insulating layer IL5 is arranged above the pixel electrode PTCO. The common auxiliary electrode CMTL and the common electrode CTCO are arranged above the insulating layer IL5. That is, the pixel electrode PTCO faces the common electrode CTCO via the insulating layer IL5. The common electrode CTCO is connected to the common auxiliary electrode CMTL at the opening PCON (in the second contact area CON2). As will be described in detail later, the common auxiliary electrode CMTL and the common electrode CTCO have different patterns respectively when seen in a plan view. The common auxiliary electrode CMTL is a metal layer. The common electrode CTCO is a transparent conductive layer. The electric resistance of the common auxiliary electrode CMTL is lower than the electric resistance of the common electrode CTCO. The common auxiliary electrode CMTL also functions as a light-shielding layer. For example, the common auxiliary electrode CMTL shields light from adjacent pixels to suppress the occurrence of color mixture. A spacer SP is arranged above the common electrode CTCO.

The spacer SP is arranged for part of the pixels. For example, the spacer SP may be arranged for any one of a blue pixel, a red pixel and a green pixel. However, the spacer SP may be arranged for all the pixels. A height of the spacer SP is half the height of a cell gap. A spacer is also arranged on a counter substrate, and overlaps the spacer on the counter substrate and the above spacer SP in a plan view.

A light-shielding layer LS (LS1, LS2) is arranged between the transistor Tr1 and the substrate SUB. In the present embodiment, light-shielding layers LS1 and LS2 are arranged as the light-shielding layer LS. However, the light-shielding layer LS may be formed of only the light-shielding layer LS1 or LS2. In a plan view, the light-shielding layer LS is arranged in an area where the gate electrode GL1 and the oxide semiconductor layer OS overlap. That is, in a plan view, the light-shielding layer LS is arranged in an area overlapping the oxide semiconductor layer OS1. As will be described in detail later, an end portion of the opening ZCON side of the light-shielding layer LS overlaps the opening ZCON. The light-shielding layer LS suppresses the light incident from the substrate SUB side from reaching the oxide semiconductor layer OS1. In the case where a conductive layer is used as the light-shielding layer LS, a voltage may be applied to the light-shielding layer LS to control the oxide semiconductor layer OS1. In the case where a voltage is applied to the light-shielding layer LS, the light-shielding layer LS and the gate electrode GL1 may be connected at a peripheral area of the pixel circuit. In a plan view, the above first contact area CON1 is arranged such as a part of the first contact area CON1 overlaps the light-shielding layer LS.

### [1-3. Configuration of Transistor Tr2]

The transistor Tr2 has a p-type transistor Tr2-1 and an n-type transistor Tr2-2.

The p-type transistor Tr2-1 and the n-type transistor Tr2-2 both include a gate electrode GL2, a gate insulating layer GI2, and a semiconductor layer S (S1 to S3). The gate electrode GL2 faces the semiconductor layer S. The gate insulating layer GI2 is arranged between the semiconductor layer S and the gate electrode GL2. In the present embodiment, although a bottom gate type transistor in which the gate electrode GL2 is arranged closer to the substrate SUB than the semiconductor layer S is exemplified, a top gate type transistor in which a positional relationship between the semiconductor layer S and the gate electrode GL2 is reversed may be used as the display device.

The semiconductor layer S of the p-type transistor Tr2-1 includes semiconductor layers S1 and S2. The semiconductor layer S of the n-type transistor Tr2-2 includes semiconductor layers S1, S2 and S3. The semiconductor layer S1 is a semiconductor layer overlapping the gate electrode GL2 in a plan view. The semiconductor layer S1 functions as a channel for the transistor Tr2-1. The semiconductor layer S2 functions as a conductive layer. The semiconductor layer S3 functions as a conductive layer with a higher resistance than the semiconductor layer S2. The semiconductor layer S3 suppresses hot carrier degradation by attenuating hot carriers intruding toward the semiconductor layer S1.

An insulating layer IL1 and the gate insulating layer GI1 are arranged on the semiconductor layer S. In the transistor Tr2, the gate insulating layer GI1 simply functions as an interlayer film. A wiring W2 is arranged above these insulating layers. The wiring W2 is connected to the semiconductor layer S via an opening arranged in the insulating layer IL1 and the gate insulating layer GI1. The insulating layer IL2 is arranged on the wiring W2. The wiring W1 is arranged on the insulating layer IL2. The wiring W1 is connected to the wiring W2 via an opening arranged in the insulating layer IL2.

The gate electrode GL2 and the light-shielding layer LS2 are the same layer. The wiring W2 and the gate electrode GL1 are the same layer. The same layer means that multiple members are formed by patterning one layer.

### [1-4. Configuration of Opening ZCON]

FIG. 1B is an enlarged view of a vicinity of the opening ZCON in FIG. 1A and a plan view corresponding to the enlarged view. A configuration of the opening ZCON will be described with reference to FIG. 1B. Specifically, configurations of the connecting electrode ZTCO and the barrier layer ZPS arranged in the opening ZCON will be described. The cross-sectional view of FIG. 1B is a cross-sectional view taken along A-A′ line in the plan view of FIG. 1B.

As shown in FIG. 1B, the opening ZCON is arranged in the gate insulating layer GI1 and the insulating layers IL2 and IL3. The opening ZCON reaches the oxide semiconductor layer OS arranged below the gate insulating layer GI1.

In the open ZCON shown in the cross-sectional view of FIG. 1B, the first side wall SW1 is covered by the connecting electrode ZTCO and the second side wall SW2 is not covered by the connecting electrode ZTCO. That is, in the second side wall SW2, there is an area where the connecting electrode ZTCO is not arranged. In the present embodiment, the first side wall SW1 is in contact with the connecting electrode ZTCO and is not in contact with the barrier layer ZPS arranged on the connecting electrode ZTCO. On the other hand, the second side wall SW2 is in contact with the barrier layer ZPS. In the present embodiment, although a configuration in which the connecting electrode ZTCO is in contact with the first side wall SW1 and the barrier layer ZPS is in contact with the second side wall SW2 is exemplified, the configuration is not limited to this configuration. For example, another member may be arranged between the connecting electrode ZTCO and the first side wall SW1. Similarly, other members may be arranged between the barrier layer ZPS and the second side wall SW2.

Each of the first side wall SW1 and the second side wall SW2 means at least one of side walls of the gate insulating layer GI1 and the insulating layers IL2 and IL3. That is, for example, the expression that the connecting electrode ZTCO is in contact with the first side wall SW1 means that the connecting electrode ZTCO is in contact with at least one of the side walls of the gate insulating layer GI1 and the insulating layers IL2 and IL3.

The first side wall SW1 and the second side wall SW2 are both inclined with respect to a direction ND perpendicular to a main surface of the substrate SUB. In the present embodiment, both of the first side wall SW1 and the second side wall SW2 are inclined at an inclination angle α with respect to the main surface of the substrate SUB. The angle is an angle between an upper surface of the oxide semiconductor layer OS and a lower end portion of a side wall (SW1 or SW2) in the cross section. The angular range is preferably from 50° to 80°, more preferably from 60° to 75°. In the case where a cross-sectional shape of the side wall is arcuate, the inclination angle α refers to the angle between the lower end portion of the side wall and the upper surface of the oxide semiconductor layer. Here, although one of the sides constituting the inclination angle α is defined as the upper surface of the oxide semiconductor layer in the cross section, a lower surface (the gate insulating layer GI1 in FIG. 1B) of the layer located in the lowermost layer among the insulating layers forming the opening ZCON may be defined as the side constituting the inclination angle α.

As shown in the plan view of FIG. 1B, the connecting electrode ZTCO is arranged in the bottom of the opening ZCON, the side wall (the first side wall SW1) of the opening ZCON, and an area other than the opening ZCON in the first area CR1. In the plan view of FIG. 1B, a circular area sandwiched by two dotted lines corresponds to the side wall of the opening ZCON. Of these side walls, the side wall existing in the first area CR1 corresponds to the first side wall SW1, and the side wall existing in the second area CR2 corresponds to the second side wall SW2. Although a configuration in which the opening ZCON is rectangular is shown in a plan view of FIG. 1B, the present invention is not limited to this configuration. For example, the shape of the opening ZCON in a plan view may be a round shape at the corner of the rectangle, or a circular shape as shown in FIG. 1C.

The first area CR1 is an area overlapping the light-shielding layer LS in plan view. The second area CR2 is an area that does not overlap the light-shielding layer LS in a plan view. That is, in a plan view, the connecting electrode ZTCO is arranged in an area overlapping the first side wall SW1, and the connecting electrode ZTCO is not arranged in an area overlapping the second side wall SW2. However, the connecting electrode ZTCO may be arranged in part of the second side wall SW2 (for example, around the lower edge portion of the opening ZCON).

As shown in the plan view of FIG. 1B, the connecting electrode ZTCO is arranged in the first area CR1 and is not arranged in the second area CR2 at the side wall of the opening ZCON and an upper portion of the insulating layer IL3. On the other hand, at the bottom of the opening ZCON, the connecting electrode ZTCO is arranged in both the first area CR1 and the second area CR2. That is, the connecting electrode ZTCO is in contact with the oxide semiconductor layer OS exposed at the bottom of the opening ZCON in the second area CR2 that does not overlap the light-shielding layer LS.

In the present embodiment, although a configuration in which the connecting electrode ZTCO covers all of the bottom portions of the opening ZCON is exemplified, the configuration is not limited to this configuration. For example, an area where the connecting electrode ZTCO is not arranged may be present at the bottom of the opening ZCON. That is, part of the bottom portion of the opening ZCON may be exposed from the connecting electrode ZTCO. Even in such cases, the connecting electrode ZTCO is arranged at the bottom of the opening ZCON in the second area CR2. In other words, the end portion of the connecting electrode ZTCO at the bottom portion of the opening ZCON protrudes from an end portion of the connecting electrode ZTCO in an area other than the opening ZCON in a first direction DA, which is a direction from the first side wall SW1 toward the second side wall SW2. In other words, the connecting electrode ZTCO extends in the first direction DA beyond the end portion of the light-shielding layer LS from the area overlapping the light-shielding layer LS in a plan view. An end portion of the opening ZCON positioned in the first direction DA than the end portion of the connecting electrode ZTCO in a plan view.

The ratio of the connecting electrode ZTCO covers the bottom of the opening ZCON is 60% or more, 70% or more, 80% or more, or 90% or more of an area of the bottom portion (the ratio is 100% in FIG. 1B plan view). In the case where there is the area of the bottom portion of the opening ZCON where the connecting electrode ZTCO is not arranged, the oxide semiconductor layer OS, the insulating layer IL1, and the like arranged below the connecting electrode ZTCO may be etched in the area in a etching process of the connecting electrode ZTCO. Therefore, the ratio of the connecting electrode ZTCO covering the bottom of the opening ZCON is preferably 60% or more. However, in the case where the oxide semiconductor layer OS is not etched in the etching process of the connecting electrode ZTCO, the ratio may be less than 60%.

In the present embodiment, although a configuration in which the connecting electrode ZTCO is in contact with only the lower portion of the gate insulating layer GI1 in the second side wall SW2 is exemplified, the configuration is not limited to this configuration. For example, the connecting electrode ZTCO may be in contact with part of the insulating layers IL2 and IL3 of the second side wall SW2.

### [1-5. Effects Obtained by the Configuration of the Opening ZCON]

In the present embodiment, the connecting electrode ZTCO and the oxide semiconductor layer OS have light-transmitting properties, and part of the first contact area CON1 is located in a display area (sometimes referred to as a “light-transmitting area” or an “opening area”) of the pixel. In this case, when the light enters the display device 10 in a direction perpendicular to the main surface of the substrate SUB, the light is refracted at the inclined side wall of the opening ZCON, and a polarization state of the light is changed. Specifically, in the case where the display device 10 is a liquid crystal display device, although linearly polarized light enters the display device 10, such linearly polarized light changes at the inclined side wall of the opening ZCON, and the polarization state changes from linearly polarized light to a state close to circularly polarized light. Due to this change in polarization, the light that should originally be shielded by the polarizing plate arranged on a CF substrate may be transmitted through the polarizing plate (light leakage occurs), and the contrast of the images may be reduced.

This phenomena is remarkable in the case where the side wall of the opening ZCON is inclined at an inclination angle α with respect to the main surface of the substrate SUB. Therefore, this phenomena is unlikely to occur at the bottom portion of the opening ZCON or at an upper portion of the insulating layers IL2 and IL3, and occur mainly in a vicinity of an area overlapping the side wall of the opening ZCON in a plan view. Particularly, in the case where a material having a high refractive index such as ITO is used as the connecting electrode ZTCO, an effect of the above phenomena is large.

In the display device 10 according to the present embodiment, although the connecting electrode ZTCO is arranged on the first side wall SW1 presenting in the first area CR1 that overlaps the light-shielding layer LS in a plan view, the connecting electrode ZTCO is not arranged on the second side wall SW2 presenting in the second area CR2 that does not overlap the light-shielding layer LS in a plan view. In the first side wall SW1, although the polarization state is changed by the connecting electrode ZTCO, since the first side wall SW1 overlaps the light-shielding layers LS in a plan view, even if the polarization state is changed, the displayed images are not affected. On the other hand, since the connecting electrode ZTCO is not arranged in the second side wall SW2 existing in the light-transmitting area, the polarization status does not change due to the connecting electrode ZTCO. Therefore, the light leakage describe above is less likely to occur, and a display device having high display performance can be realized.

Further, in the display device 10 according to the present embodiment, as shown in FIG. 1B, the barrier layer ZPS having moisture barrier property is arranged on the insulating layer IL3. In the case where a resin layer such as acryl is used as the planarization film as the insulating layer IL4 arranged on the barrier layer ZPS, water contained in the resin layer passes through the bottom portion of the opening ZCON and reaches the oxide semiconductor layer OS, and causes oxygen vacancies in the oxide semiconductor layer OS. However, since the barrier layer ZPS is arranged not only on the insulating layer IL3 but also inside the opening ZCON as in the display device 10 according to the present embodiment, it is possible to prevent that moisture from the insulating layer IL4 reaches the oxide semiconductor layer OS. The barrier layers ZPS are arranged continuously from the side wall to the bottom of the opening ZCON. As will be described later, for example, a silicon nitride layer is used as the barrier layer ZPS.

As described above, if the barrier layer ZPS is arranged on the connecting electrode ZTCO in order to suppress generation of oxygen vacancy in the oxide semiconductor layer OS due to moisture from the insulating layer IL4, the light incident on the side wall of the opening ZCON is affected by the refraction generated between the connecting electrode ZTCO and the barrier layer ZPS in addition to the refraction generated between the connecting electrode ZTCO and the respective insulating layers (IL3, IL2, and GI1) in the side wall. In particular, in the case where a silicon nitride layer is used as the barrier layer ZPS, a refractive index of the silicon nitride layer is large, so that the change in the polarization state is larger than that in the case where the barrier layer ZPS is not arranged.

As described above, even in the case where the barrier layer ZPS is used, the connecting electrode ZTCO is not arranged on the second side wall SW2, and only the barrier layer ZPS is arranged on the second side wall SW2, so that it is possible to suppress a change in the polarization status as compared with a case where both the connecting electrode ZTCO and the barrier layer ZPS are arranged as in the first side wall SW1.

On the other hand, in the first directional DA, since the end portion of the connecting electrode ZTCO at a bottom portion of the opening ZCON protrudes from the end portion of the connecting electrode ZTCO in the area other than the opening ZCON, a contact area between the oxide semiconductor layer OS and the connecting electrode ZTCO can be secured at the bottom portion of the opening ZCON. Therefore, it is possible to suppress an increase in a contact resistance between the oxide semiconductor layer OS and the connecting electrode ZTCO, and realize a configuration in which the connecting electrode ZTCO is not arranged on the second side wall SW2 as described above.

### [1-6. Plan Layout of Display Device 10]

A plan layout of a pixel of the display device 10 will be described with reference to FIG. 2 to FIG. 13. In FIG. 2, the pixel electrode PTCO, the common auxiliary electrode CMTL, the common electrode CTCO, and the spacer SP are omitted. The plan layout of the pixel electrode PTCO, the common auxiliary electrode CMTL, and the common electrode CTCO are shown in FIG. 11 to FIG. 13, respectively.

As shown in FIG. 2 and FIG. 3, the light-shielding layer LS extends in a direction D1. A shape of the light-shielding layer LS may be different depending on the pixel. In the present embodiment, a protruding part PJT protruding in a direction D2 is arranged from part of the light-shielding layer LS extending in the direction D1. As shown in FIG. 5, the light-shielding layer LS is arranged in an area including the area where the gate electrode GL1 and the oxide semiconductor layer OS overlap in a plan view. The gate electrode GL1 can also be referred to as a “gate line.”

As shown in FIG. 2, FIG. 4, and FIG. 5, the oxide semiconductor layer OS extends in the direction D2. The gate electrode GL1 extends in the direction D1 so as to intersect the oxide semiconductor layer OS. A pattern of the gate electrode GL1 is arranged inside a pattern of the light-shielding layer LS. In other words, the oxide semiconductor layers OS is formed in a long shape intersecting the gate electrode GL1.

As shown in FIG. 2, FIG. 6, and FIG. 7, the opening WCON is arranged in an area overlapping the wiring W1 near an upper end of the pattern of the oxide semiconductor layer OS. A main part of the pattern of the oxide semiconductor layer OS extends in the direction D2 between a pair of the adjacent wirings W1 (W1-1 and W1-2). In the case where it is necessary to distinguish the adjacent wirings W1 from each other, the adjacent wirings W1 are referred to as a first wiring W1-1 and a second wiring W1-2. The remaining part of the pattern of the oxide semiconductor layer OS extends obliquely in the direction D1 and the direction D2 from the main part and overlaps the opening WCON.

As shown in FIG. 2 and FIG. 7, multiple wirings W1 extend in the direction D2. In this case, it can be said that the main part of the oxide semiconductor layer OS extends in the direction D2 between the first wiring W1-1 and the second wiring W1-2, and intersects the gate electrode GL1. In other words, the oxide semiconductor layer OS is arranged in a long shape in the direction D2 (shape having a longitudinal) and connected to the wiring W1-1 at one end in a longitudinal direction of the oxide semiconductor layer OS.

As shown in FIG. 2, FIG. 8, and FIG. 9, the opening ZCON is arranged near a lower end of the pattern of the oxide semiconductor layer OS. The opening ZCON is arranged in an area overlapping the pattern of the oxide semiconductor layer OS and not overlapping the gate electrode GL1.

Part of the opening ZCON overlaps the light-shielding layer LS. An area overlapping the light-shielding layer LS in FIG. 8 corresponds to the first area CR1 in FIG. 1B. An area that does not overlap the light-shielding layer LS in FIG. 8 corresponds to the second area CR2 in FIG. 1B. In FIG. 8, part of the side wall of the opening ZCON overlapping the light-shielding layer LS corresponds to the first side wall SW1 in FIG. 1B. In FIG. 8, part of the side wall of the opening ZCON that does not overlap the light-shielding layer LS corresponds to the second side wall SW2 in FIG. 1B.

The opening ZCON is arranged in an area overlapping the connecting electrode ZTCO. The connecting electrode ZTCO overlaps the gate electrode GL1 and the oxide semiconductor layer OS between the first wiring W1-1 and the second wiring W1-2. Therefore, the connecting electrode ZTCO is in contact with the oxide semiconductor layer OS in the opening ZCON (the first contact area CON1) not overlapping the gate electrode GL1. Since the configuration of opening ZCON and the connecting electrode ZTCO is the same as the configuration shown in FIG. 1B, so a detail explanation is omitted.

In other words, the oxide semiconductor layer OS is connected to the connecting electrode ZTCO at the other end in the longitudinal direction of the oxide semiconductor layer OS. The connecting electrode ZTCO is formed in a long shape extending in the direction D2 similar to the oxide semiconductor layer OS. In the direction D1, a width of the connecting electrode ZTCO is smaller than a width of the oxide semiconductor layer OS.

As shown in FIG. 2, FIG. 7, and FIG. 8, the oxide semiconductor layer OS is in contact with the wiring W1 at the opposite side of the opening ZCON (first contact area CON1) with respect to the gate electrode GL1.

As shown in FIG. 2, FIG. 10, and FIG. 11, the opening PCON is arranged near an upper end of a pattern of the connecting electrode ZTCO. The opening PCON is arranged in an area overlapping the pattern of the gate electrode GL1 and the pattern of the connecting electrode ZTCO. The opening PCON is arranged in an area overlapping the pixel electrode PTCO (PTCO1˜4). The pixel electrode PTCO overlaps the gate electrode GL1, the oxide semiconductor layer OS, and the connecting electrode ZTCO between the first wiring W1-1 and the second wiring W1-2. Therefore, the pixel electrode PTCO is in contact with the connecting electrode ZTCO in the opening PCON (the second contact area CON2) overlapping the gate electrode GL1.

The pixel electrode PTCO extends in the display area as described below. In other words, the pixel electrode PTCO is formed in an elongated shape extending in the direction D2 similar to the oxide semiconductor layer OS and the first wiring W1-1. In the direction D1, a width of the pixel electrode PTCO is larger than the width of the oxide semiconductor layer OS.

As shown in FIG. 11, the connecting electrode ZTCO is formed in an elongated shape extending along the first wiring W1-1. In the direction D1, a width of the opening PCON constituting the second contact area CON2 is larger than the width of the connecting electrode ZTCO. In a plan view, the entire connecting electrode ZTCO overlaps the pixel electrode PTCO.

As shown in FIG. 11, the pixel electrodes PTCO are aligned in the direction D2. Among the pixels corresponding to the pixel electrode PTCO adjacent in the direction D2, one of the pixels is referred to as a “first pixel”, and another of the pixels is referred to as a “second pixel”. For example, the first pixel is a pixel corresponding to the upper pixel electrode PTCO1 among the pixel electrodes PTCO alined in the direction D2 in FIG. 11. The second pixel is a pixel corresponding to the lower pixel electrode PTCO2 among the pixel electrodes PTCO alined in the direction D2. In this case, pixel signals are supplied from the first wiring W1-1 to the first pixel and the second pixel.

The pixel electrodes PTCO are also arranged in the direction D1. A pixel adjacent to the first pixel in direction D1 may be referred to as a “third pixel”, and a pixel adjacent to the second pixel in direction D1 may be referred to as a “fourth pixel”. For example, the third pixel is a pixel corresponding to the pixel electrode PTCO3 aligned with the pixel electrode PTCO1 in the direction D1 in FIG. 11. The fourth pixel is a pixel corresponding to the pixel electrode PTCO4 aligned with the pixel electrode PTCO2 in the direction D1 in FIG. 11. The third pixel and the fourth pixel adjoin each other in direction D2. The third pixel and the fourth pixel are supplied with pixel signals from the second wiring W1-2 adjacent to the first wiring W1-1.

As described above, each of the first pixel, the second pixel, the third pixel, and the fourth pixel has the transistor Tr1 (a pixel transistor), the connecting electrode ZTCO, and the pixel electrode PTCO.

In other words, the transistor Tr1 includes the oxide semiconductor layer OS, the gate electrode GL1 facing the oxide semiconductor layer OS, the gate insulating layer OS between the oxide semiconductor layer and the gate electrode GL1, the light-shielding layer LS overlapping part of the oxide semiconductor layer OS in a plan view, the first insulating layer (insulating layers IL2 and IL3), and the transparent conductive layer (connecting electrode ZTCO). The first insulating layer covers the oxide semiconductor layer OS, the gate electrode GL1, and the gate insulating layer GI1. The first insulating layer is arranged with the first opening having the first side wall SW1 and the second side wall SW2. The first side wall SW1 overlaps the light-shielding layer LS in a plan view. The second side wall SW2 does not overlap the light-shielding layer LS in a plan view. In other words, the barrier layer ZPS faces the first side wall ZTCO via the connecting electrode SW1 and faces the second side wall SW2 without the connecting electrode ZTCO. The connecting electrode ZTCO is arranged in the area overlapping the first side wall SW1 in a plan view. The connecting electrode ZTCO is not arranged in the area overlapping the second side wall SW2 in a plan view.

In a plan view, the pixel electrode PTCO1 of the first pixel arranged in an upper side of FIG. 11 overlaps the oxide semiconductor layer OS of the first pixel and the oxide semiconductor layer OS of the second pixel arranged in a lower side of the first pixel. The pixel electrode PTCO1 of the first pixel overlaps the oxide semiconductor layer OS of the third pixel in a plan view.

As shown in FIG. 12, the common auxiliary electrode CMTL is arranged in a grid shape so as to surround the periphery of the pixel area. That is, the common auxiliary electrode CMTL is arranged in common for multiple pixels. In other words, the common auxiliary electrode CMTL has an opening OP. The opening OP is arranged so as to expose an area where the pixel electrode PTCO and the opening ZCON (first contact area CON1) are arranged. The area in which the opening OP is arranged corresponds to the display area. That is, the opening ZCON is included in the display area. Therefore, if a high refractive index material having a predetermined thickness or more is arranged on the inclined side wall of the opening ZCON, a change in the polarization state occurs there. The display area means an area where a user can visually recognize light from a pixel. For example, an area shielded by the metal layer and not visible to the user is not included in the display area.

As shown in FIG. 13, the common electrode CTCO is arranged commonly for multiple pixels. A slit SL is arranged in an area corresponding to the above opening OP. The slit SL has a curved shape (longitudinally long S-shape). A tip of the slit SL has a shape in which a width orthogonal to an extending direction of the tip is reduced. Referring to FIG. 1A and FIG. 13, the common electrode CTCO has the slit SL at a position facing the pixel electrode PTCO.

### [1-7. Forming Method of Connecting Electrode ZTCO Formed on Opening ZCON]

A forming method of the connecting electrode ZTCO formed on the opening ZCON will be described with reference to FIG. 14 to FIG. 18. FIG. 14 to FIG. 18 are cross-sectional views showing a manufacturing method of a display device according to the embodiment of the present invention. As shown in FIG. 1A, after the oxide semiconductor layer OS, the gate electrode GL1 facing the oxide semiconductor layer OS, and the gate insulating layer GI1 between the oxide semiconductor layer OS and the gate electrode GL1 are formed, the first insulating layer (insulating layers IL2 and IL3) is formed thereon.

As shown in FIG. 14, after the opening ZCON is formed in the gate insulating layer GI1 and the insulating layers IL2 and IL3, the connecting electrode ZTCO is formed inside the opening ZCON. This step forms a connecting electrode ZTCO on the upper surface of the insulating layer IL3, on the first side wall SW1, on the second side wall SW2, and on the bottom portion of the opening ZCON.

As shown in FIG. 15, a resist RES is applied on the connecting electrode ZTCO. In a step of applying the resist RES, since the resist RES is fluidic, the resist RES flows into the opening ZCON. Consequently, a thickness T1 of the resist RES arranged vertically above the opening ZCON is larger than a thickness T2 of the resist RES arranged vertically above the insulating layers IL3.

As shown in FIG. 16, while the first area CR1 is covered with a mask MASK, an exposure process is performed on the resist RES via the mask MASK. The resist RES is altered by the exposure process. In FIG. 16, the resist RES altered by the exposure process and the resist RES not altered are shown with different hatchings. With respect to the resist RES formed in the second area CR2, all the resists RES included in the thickness T2 are altered. On the other hand, with respect to the resist RES formed inside the opening ZCON, part of the resist RES in the thickness T1 is altered, but the resist RES in a vicinity of the bottom portion of the opening is not altered. This is because T1 is larger than T2, so that the light irradiated by the exposure process does not reach the resist RES in the vicinity of the bottom portion of the opening ZCON.

If the resist RES altered as described above is removed, as shown in FIG. 17, in the second area CR2, a configuration is obtained in which, in the connecting electrode ZTCO formed on the second side wall SW2 is exposed from the resist RES, and the bottom portion of the opening ZCON is covered with the resist RES. If the connecting electrode ZTCO is etched in this condition, although most of the connecting electrodes ZTCO formed on the second side wall SW2 are etched, the connecting electrode ZTCO at the bottom portion of the opening ZCON is not etched. Consequently, as shown in FIG. 18, the second side wall SW2 is exposed from the connecting electrode ZTCO, and the bottom portion of the opening ZCON is covered with the connecting electrode ZTCO.

Although the present embodiment exemplifies the manufacturing method using a positive resist in which a portion in which the resist RES is altered is removed by the exposure process, the present invention is not limited to this manufacturing method. For example, the manufacturing method may be adopted in which a negative resist is used in which the portion that has been altered by the exposure process is not removed but remains, and a portion that has not been altered is removed. In this process, the exposure process is performed on the first area CR1 using the masking MASK.

### [1-8. Materials of Each Member of Display Device 10]

A rigid substrate having light transmittance and no flexibility, such as a glass substrate, a silica substrate, and a sapphire substrate can be used as the substrate SUB. On the other hand, in the case where the substrate SUB needs to have flexibility, a flexible substrate containing a resin and having flexibility, such as a polyimide substrate, an acrylic substrate, a siloxane substrate, or a fluororesin substrate can be used as the substrate SUB. In order to improve the heat resistance of the substrate SUB, impurities may be introduced into the above resin.

General metal materials can be used as the gate electrode GL1 and GL2, the wirings W1 and W2, the light-shielding layer LS, and the common auxiliary electrode CMTL. For example, aluminum (Al), titanium (Ti), chromium (Cr), cobalt (Co), nickel (Ni), molybdenum (Mo), hafnium (Hf), tantalum (Ta), tungsten (W), bismuth (Bi), and silver (Ag), or alloys or compounds thereof are used as members of these electrodes and the like. The above materials may be used in a single layer or a stacked layer as the members of the above electrodes and the like.

For example, a layered structure of Ti/Al/Ti is used as the gate electrode GL1. In the present embodiment, patterned end portions of the gate electrode GL1 having the layered structure described above have a forward tapered shape.

General insulating materials can be used as the gate insulating layers GI1, GI2, and the insulating layers IL1 to IL5. For example, inorganic insulating layers such as silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), aluminum nitride (AlNₓ), and the like can be used as the insulating layers IL1 to IL3, and IL5. Low-defect insulating layers can be used as these insulating layers. Organic insulating materials such as a polyimide resin, an acrylic resin, an epoxy resin, a silicone resin, the fluororesin, or a siloxane resin can be used as the insulating layer IL4. The above organic insulating materials may be used as the gate insulating layers GI1 and GI2, and the insulating layers IL1 to IL3, and IL5. The above materials may be used in a single layer or a stacked layer as a member of the insulating layer and the like.

SiOₓ with a thickness of 100 nm is used as the gate insulating layer GI1 as an example of the above insulating layer. SiOₓ/SiNₓ/SiOₓ with a total thickness of 600 nm to 700 nm is used as the insulating layer IL1. SiOₓ/SiNₓ with a total thickness of 60 nm to 100 nm is used as the gate insulating layer GI2. SiOₓ/SiNₓ/SiOₓ with a total thickness of 300 nm to 500 nm is used as the insulating layer IL2. SiOₓ (single layer), SiNₓ (single layer), or a stacked layer thereof with a total thickness of 200 nm to 500 nm is used as the insulating layer IL3. The organic layer with a thickness of 2 μm to 4 μm is used as the insulating layer IL4. SiNₓ (single layer) with a thickness of 50 nm to 150 nm is used as the insulating layer IL5.

The above SiOₓN_{y} and AlOₓN_{y} are silicone compounds and aluminum compounds containing nitrogen (N) in a smaller ratio (x>y) than oxygen (O). The above SiNₓO_{y} and AlNₓO_{y} are silicon compounds and aluminum compounds containing oxygen in a smaller ratio (x>y) than nitrogen.

A metal oxide having semiconductor characteristics can be used as the oxide semiconductor layer OS. The oxide semiconductor layer OS has light transmittance. For example, an oxide semiconductor containing indium (In), gallium (Ga), zinc (Zn), and oxygen (O) can be used as the oxide semiconductor layer OS. In particular, an oxide semiconductor having a composition ratio of In:Ga:Zn:O=1:1:1:4 can be used. However, the oxide semiconductor containing In, Ga, Zn, and O used in the present embodiment is not limited to the above composition, and an oxide semiconductor having a composition different from that described above can also be used. For example, the ratio of In may be larger than that described above to improve mobility. In addition, the ratio of Ga may be larger to increase the band gap and reduce the influence of light irradiation.

Other elements may be added to the oxide semiconductor containing In, Ga, Zn, and O. For example, a metal element such as Al or Sn may be added to the oxide semiconductor. In addition to the oxide semiconductor described above, an oxide semiconductor containing In and Ga (IGO), an oxide semiconductor containing In and Zn (IZO), an oxide semiconductor containing In, Sn, and Zn (ITZO), and an oxide semiconductor containing In and W may be used as the oxide semiconductor layer OS. The oxide semiconductor layer OS may be amorphous or crystalline. The oxide semiconductor layer OS may be a mixed phase of amorphous and crystalline.

A transparent conductive layer is used as the connecting electrode ZTCO, the pixel electrode PTCO, and the common electrode CTCO. A mixture of indium oxide and tin oxide (ITO) and a mixture of indium oxide and zinc oxide (IZO) can be used as the transparent conductive layer. Materials other than the above may be used as the transparent conductive layer.

SiNₓ, SiNₓO_{y}, SiOₓN_{y}, AlOₓ, AlOₓN_{y}, AlNₓO_{y}, and AlNₓ are used as the barrier layer ZPS. The materials described above are materials having moisture barrier property.

As described above, according to the display device 10 of the present embodiment, in the second side wall SW2, since a change in the polarization status of the light incident on the display device 10 can be suppressed, a phenomenon lowering the contrast of images can be difficult to be caused, and thus a display device having a higher display performance can be realized. Further, since the barrier layer ZPS can prevent water from the insulating layer IL4 from reaching the oxide semiconductor layer OS, it is possible to prevent oxygen vacancies from occurring in the oxide semiconductor layer OS due to the effect of the water.

### [1-9. Modification of First Embodiment]

FIG. 19 is a plan view for explaining a layout of each layer in the display device according to a modification of an embodiment of the present invention. In a first embodiment, for example, a border between the first area CR1 and the second area CR2 exists near the center of the opening ZCON as shown in FIG. 1B and FIG. 9. That is, in the first embodiment described above, although a configuration has been exemplified in which a plan dimension of the area overlapping the light-shielding layer LS and a plan dimension of the area not overlapping the light-shielding layer LS are substantially the same in the opening ZCON, the configuration is not limited to this configuration. For example, as shown in FIG. 19, the plan dimension of the area of the opening ZCON overlapping with the light-shielding layer LS may be larger than the plan dimension of the area not overlapping with the light-shielding layer LS. That is, in a plan view, an area of at least half of the opening ZCON overlaps the light-shielding layer LS.

According to the configuration of the modification of the first embodiment, an area in which the second side wall SW2 is present can be made smaller than an area in which the first side wall SW1 is present. Therefore, even if the connecting electrode ZTCO is formed on the second side wall SW2, the polarization of the light can be prevented from changing.

### 2. Second Embodiment

FIG. 20 is a plan view for explaining a layout of each layer in the display device according to an embodiment of the present invention. A display device according to a second embodiment is similar to the display device 10 according to the first embodiment. Therefore, the same configuration as that of the display device 10 in the display device 10A will be omitted, and differences from the display device 10 will be mainly described.

FIG. 20 is a diagram corresponding to FIG. 9. As shown in FIG. 20, the light-shielding layer LS is arranged with a first protruding part PJT1 and a second protruding part PJT2. The first protruding part PJT1 is the same as the protruding part PJT shown in FIG. 3, and therefore will not be described. The second protruding part PJT2 is formed at a position where the opening ZCON is arranged. That is, the second protruding part PJT2 protrudes from the first side wall SW1 toward the second side wall SW2 in an area overlapping the opening ZCON in a plan view. Since the light-shielding layer LS includes the second protruding part PJT2, the plan dimension of the area overlapping with the light-shielding layer LS in the opening ZCON is larger than the plan dimension of the area not overlapping with the light-shielding layer LS.

According to the display device 10A of the second embodiment, an area in which the second side wall SW2 is present can be made smaller than an area in which the first side wall SW1 is present. Therefore, even if the connecting electrode ZTCO is formed on the second side wall SW2, the polarization of the light can be prevented from changing.

### 3. Third Embodiment

An entire configuration of the display device described in the first embodiment and the second embodiment will be described with reference to FIG. 21 to FIG. 23.

### [3-1. Outline of Display Device 20B]

FIG. 21 is a plan view showing an outline of a display device according to an embodiment of the present invention. As shown in FIG. 21, a display device includes an array substrate 300B, a seal part 400B, a counter substrate 500B, a flexible printed circuit board 600B (FPC 600B), and an IC chip 700B. The array substrate 300B and the counter substrate 500B are bonded by the seal part 400B. Multiple pixel circuits 310B are arranged in a matrix in a liquid crystal area 22B surrounded by the seal part 400B. The liquid crystal area 22B is an area overlapping a liquid crystal element 410B described later in a plan view.

A seal area 24B arranged with the seal part 400B is an area around the liquid crystal area 22B. The FPC 600B is arranged in a terminal area 26B. The terminal area 26B is an area where the array substrate 300B is exposed from the counter substrate 500B and arranged outside the seal area 24B. Further, the exterior side of the seal area means outside the area arranged with the seal part 400B and outside the area surrounded by the seal part 400B. The IC chip 700B is arranged on the FPC 600B. The IC chip 700B supplies a signal for driving each pixel circuit 310B.

### [3-2. Circuit Configuration of Display Device 20B]

FIG. 22 is a block diagram showing a circuit configuration of a display device according to an embodiment of the present invention. As shown in FIG. 22, a source driver circuit 320B and the liquid crystal area 22B where the pixel circuit 310B is arranged are adjacent in the direction D1 (column direction), and the gate driver circuit 330B and the liquid crystal area 22B are adjacent in the direction D2 (row direction). The source driver circuit 320B and the gate driver circuit 330B are arranged in the seal area 24B described above. However, the area where the source driver circuit 320B and the gate driver circuit 330B are arranged is not limited to the seal area 24B, and it may be any area as long as it is outside the area arranged with the pixel circuit 310B.

A source wiring 321B extends in the direction D1 from the source driver circuit 320B and is connected to the multiple pixel circuits 310B arranged in the direction D1. A gate wiring 331B extends in the direction D2 from the gate driver circuit 330B and is connected to the multiple pixel circuits 310B arranged in the direction D2.

The terminal area 26B is arranged with a terminal part 333B. The terminal part 333B and the source driver circuit 320B are connected by a connecting wiring 341B. Similarly, the terminal part 333B and the gate driver circuit 330B are connected by the connecting wiring 341B. Since the FPC 600B is connected to the terminal part 333B, an external device to which the FPC 600B is connected and the display device 20B are connected, and each pixel circuit 310B arranged in the display device 20B is driven by a signal from the external device.

The transistor Tr1 shown in the first embodiment and the second embodiment is used for the pixel circuit 310B. The transistor Tr2 shown in the first embodiment and the second embodiment is applied to the transistor included in the source driver circuit 320B and the gate driver circuit 330B.

### [3-3. Pixel Circuit 310B of Display Device 20B]

FIG. 23 is a circuit diagram showing a pixel circuit of a display device according to an embodiment of the present invention. As shown in FIG. 23, the pixel circuit 310B includes elements such as a transistor 800B, a storage capacitor 890B, and the liquid crystal element 410B. One electrode of the storage capacitor 890B is the pixel electrode PTCO and the other electrode is the common electrode CTCO. Similarly, one electrode of the liquid crystal element 410B is the pixel electrode PTCO and the other electrode is the common electrode CTCO. The transistor 800B includes a first gate electrode 810B, a first source electrode 830B, and a first drain electrode 840B. The first gate electrode 810B is connected to the gate wiring 331B. The first source electrode 830B is connected to the source wiring 321B. The first drain electrode 840B is connected to the storage capacitor 890B and the liquid crystal element 410B. The transistor Tr1 shown in the first embodiment and the second embodiment is applied to the transistor 800B shown in FIG. 23. In the present embodiment, for convenience of explanation, although 830B is referred to as a source electrode and 840B is referred to as a drain electrode, the function of each electrode as a source and a drain may be replaced.

Each of the embodiments described above as an embodiment of the present invention can be appropriately combined and implemented as long as they do not contradict each other. Further, the addition, deletion, or design change of components as appropriate by those skilled in the art based on each embodiment is also included in the scope of the present invention as long as it is arranged with the gist of the present invention.

It is understood that, even if the effect is different from those arranged by each of the embodiments described above, the effect obvious from the description in the specification or easily predicted by persons ordinarily skilled in the art is apparently derived from the present invention.

What is claimed is:

1. A display device comprising:
an oxide semiconductor layer;
a gate electrode facing the oxide semiconductor layer;
a gate insulating layer between the oxide semiconductor layer and the gate electrode;
a light-shielding layer overlapping part of the oxide semiconductor layer in a plan view;
a first insulating layer covering the oxide semiconductor layer, the gate electrode, and the gate insulating layer, the first insulating layer including a first opening including a first side wall overlapping the light-shielding layer and a second side wall not overlapping the light-shielding layer in a plan view; and
a transparent conductive layer arranged above the first insulating layer and connected to the oxide semiconductor layer via the first opening,
wherein
the transparent conductive layer is arranged in an area overlapping the first side wall in a plan view, and
the transparent conductive layer is not arranged in at least part in an area overlapping the second side wall in a plan view.

2. The display device according to claim 1, further comprising a second insulating layer covering a top surface of the first insulating layer and the first opening,
wherein
the transparent conductive layer is in connect with the first side wall, and
the second insulating layer covers the transparent conductive layer and the second side wall.

3. The display device according to claim 1, wherein
the transparent conductive layer is in contact with the oxide semiconductor layer exposed in a bottom portion of the first opening in an area not overlapping the light-shielding layer in a plan view.

4. The display device according to claim 2, wherein
the second insulating layer comprises:
a barrier layer having a moisture barrier property; and
a resin insulating layer arranged above the barrier layer,
the transparent conductive layer is in contact with the first side wall, and
the barrier layer covers the transparent conductive layer and the second side wall.

5. The display device according to claim 2, further comprising a pixel electrode arranged above the second insulating layer,
wherein
the second insulating layer has a second opening achieving the transparent conductive layer, and
the pixel electrode is connected to the transparent conductive layer via the second opening.

6. The display device according to claim 1, wherein
the first opening overlaps the light-shielding layer in an area larger than half of the first opening in a plan view.

7. The display device according to claim 1, wherein
the light-shielding layer protrudes in a direction from the first side wall toward the second side wall in an area overlapping the first opening in a plan view.

8. A display device comprising:
an oxide semiconductor layer;
a gate electrode facing the oxide semiconductor layer;
a gate insulating layer between the oxide semiconductor layer and the gate electrode;
a light-shielding layer overlapping part of the oxide semiconductor layer in a plan view;
a first insulating layer covering the oxide semiconductor layer, the gate electrode, the first insulating layer including a first opening overlapping the light-shielding layer in a plan view; and
a transparent conductive layer arranged above the first insulating layer and connected to the oxide semiconductor layer via the first opening,
wherein
the transparent conductive layer extends in a first direction from an area overlapping the light-shielding layer in a plan view beyond an end portion of the light-shielding layer and is separated from the end portion of the light-shielding layer, and
an end portion of the first opening is positioned from the end portion of the light-shielding layer in the first direction side with respect to an end portion of the transparent conductive layer in a plan view.

9. The display device according to claim 8, further comprising a second insulating layer covering a top surface of the first insulating layer and the first opening,
wherein
the transparent conductive layer is in contact with a side wall of the first opening in an area overlapping the light-shielding layer in a plan view, and
the second insulating layer covers the transparent conductive layer in an area overlapping the light-shielding layer and covers the side wall of the first opening in an area not overlapping the light-shielding layer in a plan view.

10. The display device according to claim 8, wherein
the transparent conductive layer is in contact with the oxide semiconductor layer exposed in a bottom portion of the first opening in an area not overlapping the light-shielding layer in a plan view.

11. The display device according to claim 9, wherein
the second insulating layer comprises:
a barrier layer having a moisture barrier property; and
a resin insulating layer arranged above the barrier layer,
the transparent conductive layer is in contact with the side wall of the first opening in the area overlapping the light-shielding layer in a plan view,
the barrier layer covers the transparent conductive layer in the area overlapping the light-shielding layer in a plan view, and covers the side wall of the first opening in the area not overlapping the light-shielding layer in a plan view.

12. The display device according to claim 9, further comprising a pixel electrode arranged above the second insulating layer,
wherein
the second insulating layer has a second opening achieving the transparent conductive layer, and
the pixel electrode is connected to the transparent conductive layer via the second opening.

13. The display device according to claim 8, wherein
the first opening overlaps the light-shielding layer in an area larger than half of the first opening in a plan view.

14. The display device according to claim 8, wherein
the light-shielding layer protrudes in the first direction in an area overlapping the first opening in a plan view.

15. A method for manufacturing display device comprising:
forming an oxide semiconductor layer, a gate electrode facing the oxide semiconductor layer, and a gate insulating layer between the oxide semiconductor layer and the gate electrode;
forming a first insulating layer above the oxide semiconductor layer, the gate electrode, and the gate insulating layer;
forming a first opening achieving the oxide semiconductor layer in the first insulating layer;
forming a transparent conductive layer above the first insulating layer and inside the first opening;
forming a resist above the transparent conductive layer so that a thickness of the resist inside the first opening is larger than a thickness of the resist above the first insulating layer;
exposing a second side wall of the first opening from the resist while a first sidewall of the first opening and a bottom portion of the first opening are covered with the resist; and
removing the transparent conductive layer arranged on the second sidewall.
